(19) United States
(12) Patent Application Publication
(10) Pub. No.: US 2022/0172951 A1
(43) Pub. Date: Jun. 2, 2022

(54) HEAT TREATMENT METHOD AND HEAT TREATMENT APPARATUS

(71) Applicant: SCREEN Holdings Co., Ltd., Kyoto (JP)

(72) Inventors: Shogo SHIGEMASU, Kyoto-shi, Kyoto (JP); Shinichi KATO, Kyoto-shi, Kyoto (JP)

(21) Appl. No.: 17/436,798

(22) PCT Filed: Jan. 16, 2020
(86) PCT No.: PCT/JP2020/001217

§ 371 Date: Sep. 7, 2021

(30) Foreign Application Priority Data
Mar. 18, 2019 (JP) 2019-049920

(51) Int. Cl. H01L 21/268; H01L 21/67; H01L 21/66; H05B 3/00; H05B 1/02; G05D 23/27

(52) U.S. Cl. CPC H01L 21/268; H01L 21/67115; H01L 21/67248; H05B 2203/032; H05B 3/0047; H05B 1/0233; G05D 23/27; H01L 22/20

(57) ABSTRACT

The semiconductor wafer is preheated at a preheating temperature, and then irradiated with a flash of light from a flash lamp. The upper radiation thermometer measures a temperature of a front-surface of a semiconductor wafer which is raised by irradiation with a flash of light. When the front-surface temperature of the semiconductor wafer measured by the upper radiation thermometer reaches the target temperature, the supply of a current to the flash lamps is stopped to lower the front-surface temperature of the semiconductor wafer. Since the supply of a current to the flash lamps is stopped when the measured temperature of the front-surface of the semiconductor wafer reaches the target temperature, the front-surface temperature of the semiconductor wafer can be accurately raised to the target temperature regardless of the front-surface state and reflectance of the semiconductor wafer.

### TECHNICAL FIELD

The present invention relates to a heat treatment method and a heat treatment apparatus which irradiate a thin plate-shaped precision electronic substrate (hereinafter simply referred to as “substrate”) such as a semiconductor wafer with a flash of light to heat the substrate.

### BACKGROUND ART

In a process for manufacturing a semiconductor device, impurity doping is an essential step for forming a p-n junction in a semiconductor wafer. At present, it is common to perform impurity doping by an ion implantation process and a subsequent annealing process. The ion implantation process is a technique for causing impurity elements such as boron (B), arsenic (As), and phosphorus (P) to ionize and to collide against the semiconductor wafer with high acceleration voltage, and physically performing impurity implantation. The implanted impurities are activated by the annealing processing. On this occasion, when the annealing time is about several seconds or more, the impurities driven in are deeply diffused by heat, and as a result, the junction depth may become too large as compared with the required depth, which may hinder the formation of a good device.

Thus, in recent years, attention has been given to flash lamp annealing (FLA) as an annealing technique for heating a semiconductor wafer in an extremely short time. The flash lamp annealing is a heat treatment technique in which irradiating a front-surface of a semiconductor wafer with a flash of light using a xenon flash lamp (hereinafter, when the term “flash lamp” is simply used, it means a xenon flash lamp) raises the temperature of only the front-surface of the semiconductor wafer implanted with impurities in an extremely short time (several milliseconds or less).

The xenon flash lamp has a spectral distribution of radiation ranging from ultraviolet to near-infrared regions. The wavelength of light emitted from the xenon flash lamp is shorter than that of light emitted from a conventional halogen lamp, and approximately coincides with a fundamental absorption band of a silicon semiconductor wafer. Thus, when a semiconductor wafer is irradiated with a flash of light from the xenon flash lamp, the temperature of the semiconductor wafer can be rapidly raised with a small amount of transmitted light. In addition, it has also turned out that the irradiation with a flash of light in an extremely short time of several milliseconds or less allows a selective temperature rise only near the front-surface of the semiconductor wafer. Therefore, the temperature rise in an extremely short time with the xenon flash lamp allows only the activation of impurities to be achieved without deep diffusion of the impurities.

As a heat treatment apparatus using such a xenon flash lamp, Patent Literature 1 discloses a heat treatment apparatus in which an insulated gate bipolar transistor (IGBT) is connected to a light emitting circuit of a flash lamp to control light emission of the flash lamp. In the apparatus disclosed in Patent Document 1, inputting a predetermined pulse signal into the gate of the IGBT makes it possible to define the waveform of the current flowing through the flash lamp to control the lamp emission and to freely adjust the front-surface temperature profile of the semiconductor wafer.

### PRIOR ART DOCUMENT

### Patent Document

Patent Document 1: Japanese Patent Application Laid-Open No. 2009-070948

### SUMMARY

### Problem to be Solved by the Invention

In the apparatus disclosed in Patent Document 1, when flash heating is performed on a plurality of semiconductor wafers, if a pulse signal with the same pattern is input into the gate of the IGBT, the front-surface heating temperature of each of the semiconductor wafers is expected to be the same. However, actually, due to the difference in the front-surface state of the semiconductor wafer, even when pulse signals with the same pattern are input into the gate of the IGBT, the front-surface temperature reached (peak temperature) of the semiconductor wafer varies. Since the front-surface temperature reached of the semiconductor wafer during flash heating directly contributes to device performance, there arises a problem that uniform device performance cannot be obtained when the front-surface temperature reached varies.

The present invention has been made in view of the above problems, and an object thereof is to provide a heat treatment method and a heat treatment apparatus capable of accurately raising the front-surface temperature of a substrate to a target temperature.

### Means to Solve the Problem

In order to solve the above problems, a first aspect of the present invention is a heat treatment method for heating a substrate by irradiating the substrate with a flash of light, the heat treatment method including: an irradiation with a flash of light step of irradiating a front-surface of a substrate with a flash of light from a flash lamp to raise a temperature of the front-surface; a temperature measurement step of measuring a temperature of the front-surface of the substrate to be raised in temperature by a radiation thermometer; and a light emission stopping step of stopping supply of a current to the flash lamp to lower a temperature of the front-surface when a temperature of the front-surface to be measured by the radiation thermometer reaches a target temperature.

In addition, a second aspect is a heat treatment method for heating a substrate by irradiating the substrate with a flash of light, the heat treatment method including: an irradiation with a flash of light step of irradiating a front-surface of a substrate with a flash of light from a flash lamp to raise a temperature of the front-surface; a temperature measurement step of measuring a temperature of the front-surface of the substrate to be raised in temperature by a radiation thermometer; a prediction step of predicting a scheduled arrival time at which a temperature of the front-surface reaches a target temperature from a temperature measurement result by the radiation thermometer; and a light emission stopping step of stopping supply of a current to the flash lamp to lower a temperature of the front-surface within a predetermined period including the scheduled arrival time predicted in the prediction step.

In addition, according to a third aspect, in the heat treatment method according to the second aspect, the light emission stopping step includes stopping supply of a current to the flash lamp at the scheduled arrival time.

In addition, according to a fourth aspect, in the heat treatment method according to the second or third aspect, the prediction step includes predicting the scheduled arrival time based on a plurality of temperature rise patterns acquired when irradiation with a flash of light is performed.

In addition, according to a fifth aspect, in the heat treatment method according to any one of the first to fourth aspects, the light emission stopping step includes turning off an IGBT connected to the flash lamp to stop supply of a current to the flash lamp.

In addition, a sixth aspect is a heat treatment apparatus configured to irradiate a substrate with a flash of light to heat the substrate, the heat treatment apparatus including: a chamber configured to accommodate a substrate; a flash lamp configured to irradiate a front-surface of the substrate accommodated in the chamber with a flash of light to raise a temperature of the front-surface; a radiation thermometer configured to measure a temperature of the front-surface of the substrate to be raised in temperature; and a switching unit configured to stop supply of a current to the flash lamp to lower a temperature of the front-surface when a temperature of the front-surface to be measured by the radiation thermometer reaches a target temperature.

In addition, a seventh aspect is a heat treatment apparatus configured to irradiate a substrate with a flash of light to heat the substrate, the heat treatment apparatus including: a chamber configured to accommodate a substrate; a flash lamp configured to irradiate a front-surface of the substrate accommodated in the chamber with a flash of light to raise a temperature of the front-surface; a radiation thermometer configured to measure a temperature of the front-surface of the substrate to be raised in temperature; a prediction unit configured to predict a scheduled arrival time at which a temperature of the front-surface reaches a target temperature from a temperature measurement result by the radiation thermometer; and a switching unit configured to stop supply of a current to the flash lamp to lower a temperature of the front-surface within a predetermined period including the scheduled arrival time predicted by the prediction unit.

In addition, according to an eighth aspect, in the heat treatment apparatus according to the seventh aspect, the switching unit stops supply of a current to the flash lamp at the scheduled arrival time.

In addition, according to a ninth aspect, in the heat treatment apparatus according to the seventh or eighth aspect, the heat treatment apparatus further includes a storage unit configured to store a plurality of temperature rise patterns acquired when irradiation with a flash of light is performed. The prediction unit predicts the scheduled arrival time based on the plurality of temperature rise patterns.

In addition, according to a tenth aspect, in the heat treatment apparatus according to any one of the sixth to ninth aspects, the switching unit includes an IGBT connected to the flash lamp.

### Effects of the Invention

According to the heat treatment method according to the first aspect, when a front-surface temperature of the substrate measured by the radiation thermometer reaches the target temperature, the supply of a current to the flash lamp is stopped to lower the front-surface temperature of the substrate, so that the front-surface temperature of the substrate can be accurately raised to the target temperature regardless of the front-surface state of the substrate.

According to the heat treatment method according to the second to fifth aspects, the scheduled arrival time at which the front-surface temperature of the substrate reaches the target temperature is predicted from the temperature measurement result by the radiation thermometer, and the supply of a current to the flash lamp is stopped within the predetermined period including the scheduled arrival time to lower the front-surface temperature of the substrate, so that the front-surface temperature of the substrate can be accurately raised to the target temperature regardless of the front-surface state of the substrate.

According to the heat treatment apparatus according to the sixth aspect, when a front-surface temperature of the substrate measured by the radiation thermometer reaches the target temperature, the supply of a current to the flash lamp is stopped to lower the front-surface temperature of the substrate, so that the front-surface temperature of the substrate can be accurately raised to the target temperature regardless of the front-surface state of the substrate.

According to the heat treatment apparatus according to the seventh to tenth aspects, the scheduled arrival time at which the front-surface temperature of the substrate reaches the target temperature is predicted from the temperature measurement result by the radiation thermometer, and the supply of a current to the flash lamp is stopped within the predetermined period including the scheduled arrival time to lower the front-surface temperature of the substrate, so that the front-surface temperature of the substrate can be accurately raised to the target temperature regardless of the front-surface state of the substrate.

### BRIEF DESCRIPTION OF DRAWINGS

FIG. 1 is a longitudinal sectional view showing a configuration of a heat treatment apparatus according to the present invention.

FIG. 2 is a perspective view showing the entire external appearance of a holder.

FIG. 3 is a plan view of a susceptor.

FIG. 4 is a sectional view of the susceptor.

FIG. 5 is a plan view of a transfer mechanism.

FIG. 6 is a side view of the transfer mechanism.

FIG. 7 is a plan view showing an arrangement of halogen lamps.

FIG. 8 is a diagram showing a drive circuit of a flash lamp.

FIG. 9 is a block diagram showing a configuration of a high-speed radiation thermometer unit including a main part of the upper radiation thermometer.

FIG. 10 is a flowchart showing a treatment procedure of the heat treatment apparatus in the first embodiment.

FIG. 11 is a diagram showing a change in the front-surface temperature of a semiconductor wafer measured by the upper radiation thermometer.

FIG. 12 is a diagram showing an example of a waveform of a pulse signal.

FIG. 13 is a diagram showing a change in current flowing through a flash lamp.

FIG. 14 is a flowchart showing a treatment procedure of the heat treatment apparatus in the second embodiment.

FIG. 15 is a diagram showing a change in the front-surface temperature of a semiconductor wafer according to the second embodiment.

### DESCRIPTION OF EMBODIMENTS

A preferred embodiment according to the present invention will now be described in detail with reference to the drawings.

### First Embodiment

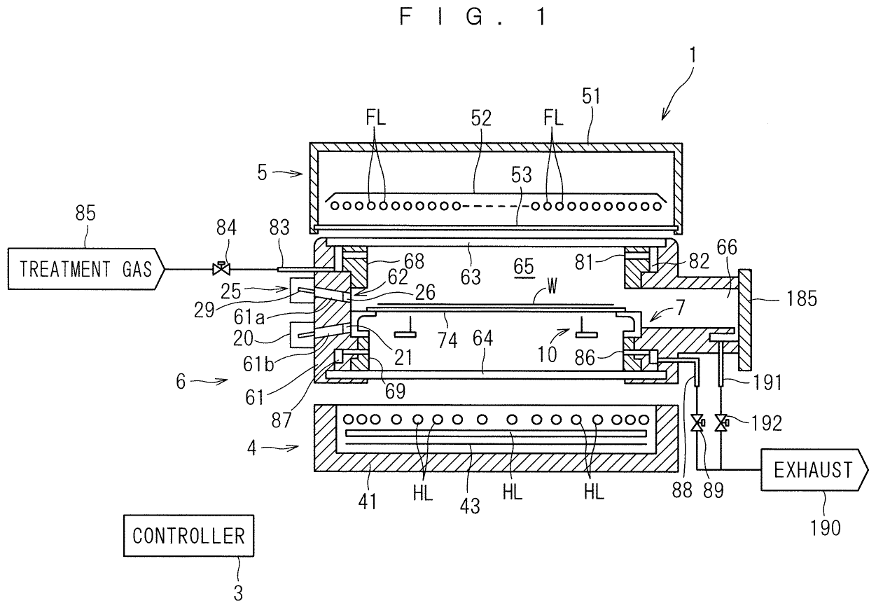

FIG. 1 is a longitudinal sectional view showing a configuration of a heat treatment apparatus 1 according to the present invention. The heat treatment apparatus 1 of FIG. 1 is a flash lamp annealer for irradiating a disk-shaped semiconductor wafer W serving as a substrate with flashes of light to heat the semiconductor wafer W. The size of the semiconductor wafer W to be treated is not particularly limited, and has a diameter of, for example, 300 mm or 450 mm (300 mm in the present embodiment). The semiconductor wafer W before being carried into the heat treatment apparatus 1 is implanted with impurities, and the activation treatment of impurities implanted by heating treatment with the heat treatment apparatus 1 is performed. It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and a halogen heating part 4 including a plurality of built-in halogen lamps HL. The flash heating part 5 is provided over the chamber 6, and the halogen heating part 4 is provided under the chamber 6. The heat treatment apparatus 1 further includes a holder 7 provided inside the chamber 6 and for holding a semiconductor wafer W in a horizontal attitude, and a transfer mechanism 10 provided inside the chamber 6 and for transferring a semiconductor wafer W between the holder 7 and the outside of the heat treatment apparatus 1. The heat treatment apparatus 1 further includes a controller 3 for controlling operating mechanisms provided in the halogen heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the halogen heating part 4 therethrough into the chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

Furthermore, a through hole 61a and a through hole 61b are drilled in the chamber side portion 61. The through hole 61a is a cylindrical hole for guiding the infrared light radiated from the upper surface of the semiconductor wafer W held by the susceptor 74 described below to the infrared sensor 29 of the upper radiation thermometer 25. On the other hand, the through hole 61b is a cylindrical hole for guiding the infrared light radiated from the lower surface of the semiconductor wafer W to the lower radiation thermometer 20. The through hole 61a and the through hole 61b are provided to be inclined with respect to the horizontal direction so that their axes in the through direction intersect with the main surface of the semiconductor wafer W held by the susceptor 74. A transparent window 26 made of a calcium fluoride material that transmits infrared light in a wavelength region measurable by the upper radiation thermometer 25 is attached to the end portion on the side facing the heat treatment space 65 of the through hole 61a. In addition, a transparent window 21 made of a barium fluoride material that transmits infrared light in a wavelength region measurable by the lower radiation thermometer 20 is attached to the end portion on the side facing the heat treatment space 65 of the through hole 61b.

At least one gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with the gas supply pipe 83 via a buffer space 82 formed in an annular shape inside the side wall of the chamber 6. The gas supply pipe 83 is connected to the treatment gas supply source 85. In addition, a valve 84 is inserted halfway through the path of the gas supply pipe 83. When the valve 84 is opened, the treatment gas is supplied from the treatment gas supply source 85 to the buffer space 82. The treatment gas flowing in the buffer space 82 flows in a spreading manner within the buffer space 82 lower in fluid resistance than the gas supply opening 81, and is supplied from the gas supply opening 81 into the heat treatment space 65. As the treatment gas, for example, an inert gas such as nitrogen (N₂), a reactive gas such as hydrogen (H₂) or ammonia (NH₃), or a mixed gas in which they are mixed can be used (nitrogen gas in the present embodiment).

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. A valve 89 is interposed in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits. In addition, the treatment gas supply source 85 and the exhaust part 190 may be mechanisms provided in the heat treatment apparatus 1, or may be utilities of a factory in which the heat treatment apparatus 1 is installed.

A gas exhaust pipe 191 for exhausting the gas from the heat treatment space 65 is also connected to a distal end of the transport opening 66. The gas exhaust pipe 191 is connected through a valve 192 to the exhaust part 190. By opening the valve 192, the gas in the chamber 6 is exhausted through the transport opening 66.

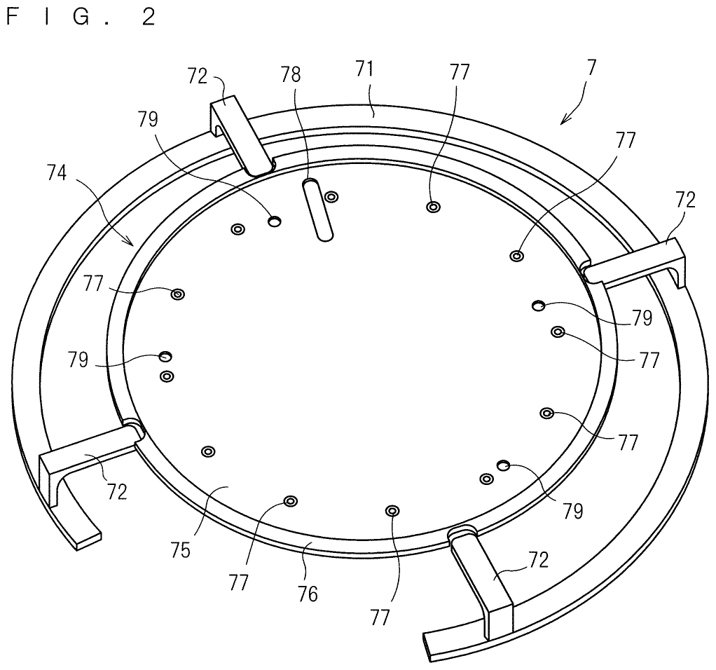

FIG. 2 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

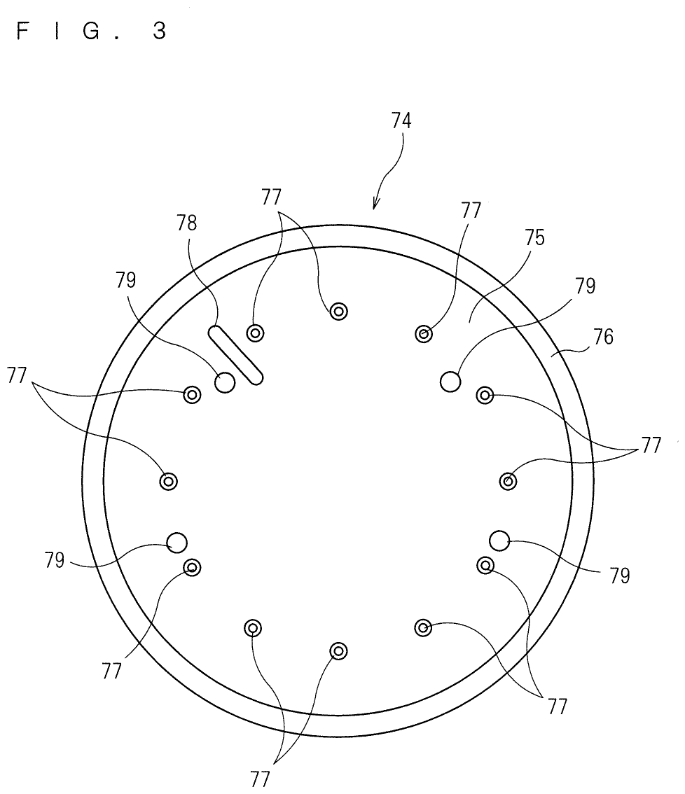

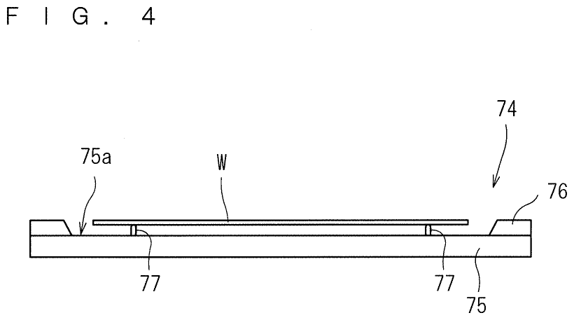

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75 of the susceptor 74. The opening 78 is provided in order for the lower radiation thermometer 20 to receive the radiation light (infrared light) radiated from the lower surface of the semiconductor wafer W. That is, the lower radiation thermometer 20 receives the light radiated from the lower surface of the semiconductor wafer W through the opening 78 and the transparent window 21 mounted on the through hole 61b of the chamber side portion 61, and measures the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

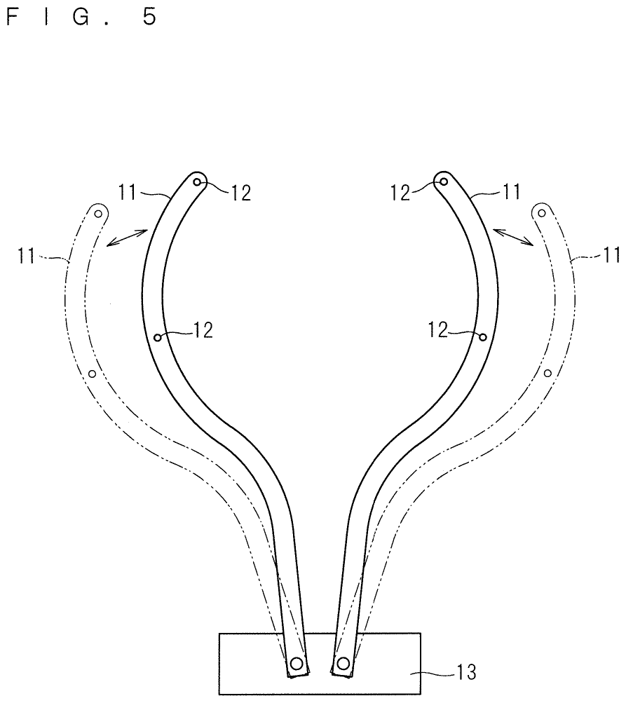

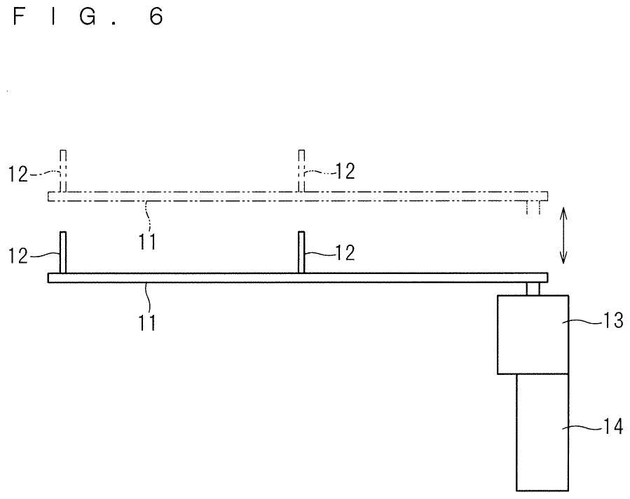

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Returning to FIG. 1, the flash heating part 5 provided above the chamber 6 is configured to include a light source including a plurality of (30 in the present embodiment) xenon flash lamps FL inside an enclosure 51 and a reflector 52 provided to cover above the light source. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane.

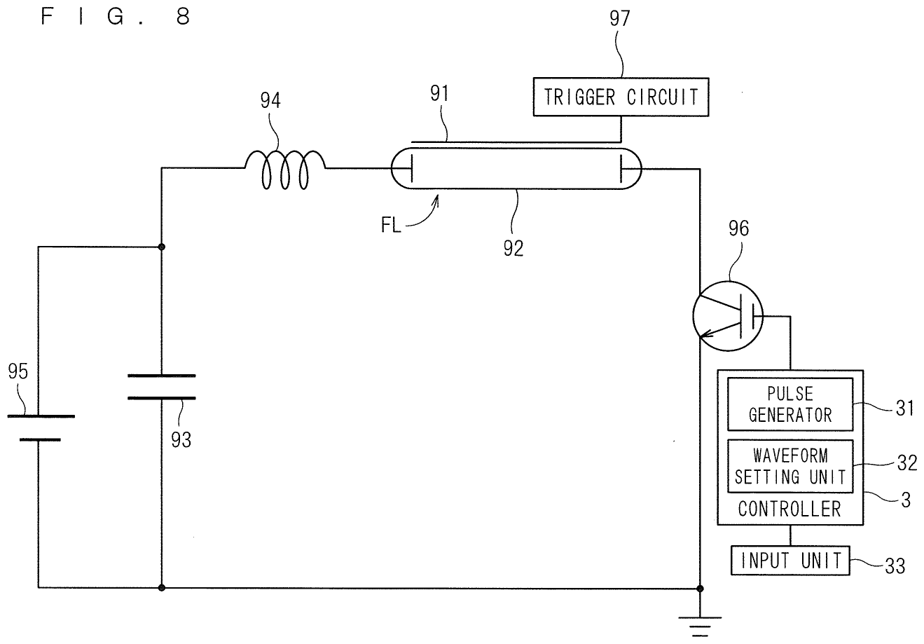

FIG. 8 is a diagram showing a drive circuit of the flash lamp FL. As shown in the figure, a capacitor 93, a coil 94, a flash lamp FL, and an insulated gate bipolar transistor (IGBT) 96 are connected in series. In addition, as shown in FIG. 8, the controller 3 includes a pulse generator 31 and a waveform setting unit 32, and is connected to the input unit 33. As the input unit 33, various known input apparatuses such as a keyboard, a mouse, and a touch panel can be adopted. The waveform setting unit 32 sets the waveform of the pulse signal based on the input content from the input unit 33, and the pulse generator 31 generates the pulse signal according to the waveform.

The flash lamp FL includes a rod-shaped glass tube (discharge tube) 92 in which xenon gas is sealed inside and an anode and a cathode are arranged at both ends thereof, and a trigger electrode 91 attached on the outer circumferential surface of the glass tube 92. The capacitor 93 is applied with a predetermined voltage by the power supply unit 95, and is charged with an electric charge corresponding to the applied voltage (charging voltage). In addition, the trigger electrode 91 can be applied with a high voltage from the trigger circuit 97. The timing at which the trigger circuit 97 applies a voltage to the trigger electrode 91 is controlled by the controller 3.

The IGBT 96 is a bipolar transistor in which a metal oxide semiconductor field effect transistor (MOSFET) is incorporated in the gate portion, and is a switching element suitable for handling a large amount of electric power. The gate of the IGBT 96 is applied with a pulse signal from the pulse generator 31 of the controller 3. When a voltage not less than a predetermined value (High voltage) is applied to the gate of the IGBT 96, the IGBT 96 comes into an ON state, and when a voltage less than the predetermined value (Low voltage) is applied, the IGBT 96 comes into an OFF state. In this way, the drive circuit including the flash lamp FL is turned on and off by the IGBT 96. Turning the IGBT 96 on and off intermittently connects between the flash lamp FL and the corresponding capacitor 93, and controls on and off the current flowing through the flash lamp FL.

Even if, with the capacitor 93 being charged, the IGBT 96 comes into an ON state and a high voltage is applied across the electrodes at both ends of the glass tube 92, the xenon gas is electrically an insulator, so that electricity does not flow in the glass tube 92 under normal conditions. However, when the trigger circuit 97 applies a high voltage to the trigger electrode 91 to break the insulation, a current flows instantly in the glass tube 92 due to the discharge between the electrodes at both ends, and light is emitted by the excitation of xenon atoms or molecules at that time.

The drive circuit as shown in FIG. 8 is individually provided for each of the plurality of flash lamps FL provided in the flash heating part 5. In the present embodiment, since thirty flash lamps FL are arranged in a plane, thirty drive circuits, each as shown in FIG. 8, are provided corresponding to them. Therefore, the current flowing through each of the thirty flash lamps FL is individually on-off controlled by the corresponding IGBT 96.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen heating part 4 provided under the chamber 6 includes an enclosure 41 incorporating the multiple (in the present preferred embodiment, 40) halogen lamps HL. The halogen heating part 4 is a light irradiation unit that heats the semiconductor wafer W by applying light from below the chamber 6 through the lower chamber window 64 to the heat treatment space 65 with a plurality of halogen lamps HL.

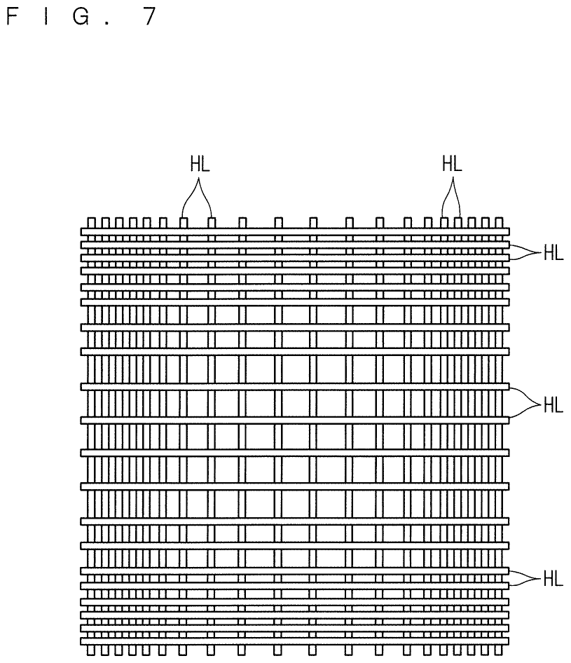

FIG. 7 is a plan view showing an arrangement of the multiple halogen lamps HL. The 40 halogen lamps HL are arranged in two tiers, i.e. upper and lower tiers. That is, 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 7, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen heating part 4 under the halogen lamps HL arranged in two tiers (FIG. 1). The reflector 43 reflects the light emitted from the halogen lamps HL toward the heat treatment space 65.

The controller 3 controls the aforementioned various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a magnetic disk for storing control software, data and the like thereon. The CPU in the controller 3 executes a predetermined processing program, whereby the processes in the heat treatment apparatus 1 proceed. In addition, the controller 3 includes a pulse generator 31 and a waveform setting unit 32 (FIG. 8). The waveform setting unit 32 sets the waveform of a pulse signal based on the input contents from the input unit 33, and the pulse generator 31 outputs the pulse signal to the gate of the IGBT 96 accordingly.

In addition, as shown in FIG. 1, the heat treatment apparatus 1 includes an upper radiation thermometer 25 and a lower radiation thermometer 20. The upper radiation thermometer 25 is a high-speed radiation thermometer for measuring a rapid temperature change on the upper surface of the semiconductor wafer W when a flash of light is applied from the flash lamp FL.

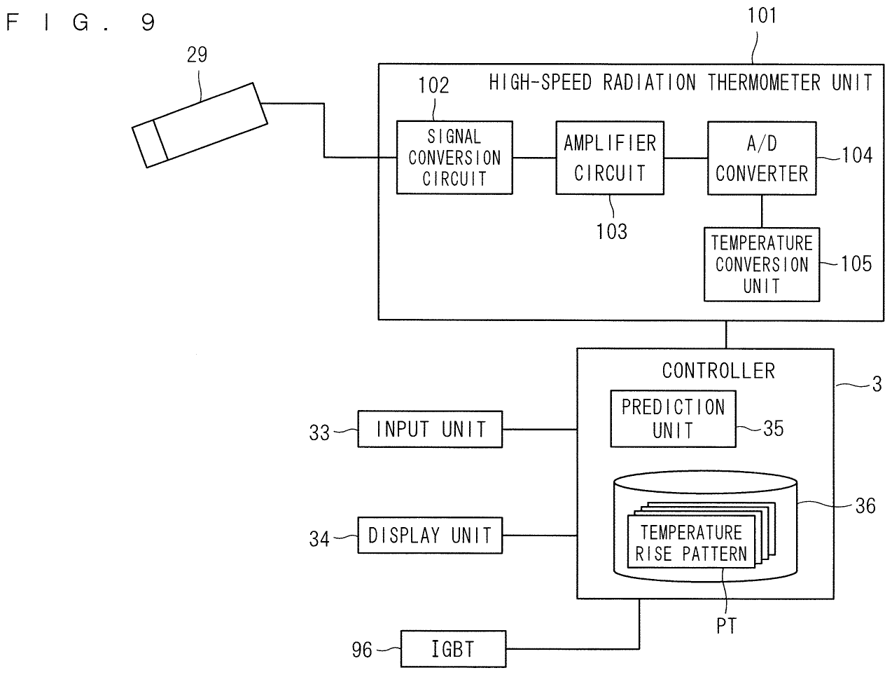

FIG. 9 is a block diagram showing a configuration of a high-speed radiation thermometer unit 101 including a main part of the upper radiation thermometer 25. The infrared sensor 29 of the upper radiation thermometer 25 is mounted on the outer wall surface of the chamber side portion 61 so that its optical axis coincides with the axis in the penetrating direction of the through hole 61a. The infrared sensor 29 receives infrared light radiated from the upper surface of the semiconductor wafer W held by the susceptor 74 through the transparent window 26 made of calcium fluoride. The infrared sensor 29 includes an InSb (indium antimonide) optical element, and its measurement wavelength range is 5 μm to 6.5 μm. The transparent window 26 made of calcium fluoride selectively transmits infrared light in the measurement wavelength range of the infrared sensor 29. The InSb optical element changes in resistance according to the intensity of the infrared light received. The infrared sensor 29 including the InSb optical element is capable of high-speed measurement with an extremely short response time and a significantly short sampling interval (a minimum of about 20 microseconds). The infrared sensor 29 is electrically connected to the high-speed radiation thermometer unit 101, and transmits a signal generated in response to light reception to the high-speed radiation thermometer unit 101.

The high-speed radiation thermometer unit 101 includes a signal conversion circuit 102, an amplifier circuit 103, an A/D converter 104, and a temperature conversion unit 105. The signal conversion circuit 102 is a circuit that signal-converts the resistance change generated by the InSb optical element of the infrared sensor 29 into the current change and voltage change in the order thereof, and finally into a voltage signal easy to handle and outputs the result. The signal conversion circuit 102 is configured using an operational amplifier, for example. The amplifier circuit 103 amplifies the voltage signal output from the signal conversion circuit 102 and outputs the result to the A/D converter 104. The A/D converter 104 converts the voltage signal amplified by the amplifier circuit 103 into a digital signal.

The temperature conversion unit 105 performs predetermined arithmetic processing on the signal output from the A/D converter 104, that is, the signal indicating the intensity of the infrared light received by the infrared sensor 29 and converts the result into temperature. The temperature obtained by the temperature conversion unit 105 is the temperature of the upper surface of the semiconductor wafer W. It should be noted that the upper radiation thermometer 25 includes an infrared sensor 29, a signal conversion circuit 102, an amplifier circuit 103, an A/D converter 104, and a temperature conversion unit 105. The lower radiation thermometer 20 has roughly the same configuration as the upper radiation thermometer 25, but does not have to support high-speed measurement.

As shown in FIG. 9, the high-speed radiation thermometer unit 101 is electrically connected to the controller 3 being the controller of the entire heat treatment apparatus 1. The controller 3 includes a prediction unit 35 in addition to the pulse generator 31 and the waveform setting unit 32 (not shown in FIG. 9). The prediction unit 35 is a functional processing unit achieved by the CPU of the controller 3 executing a predetermined processing program. The processing content of the prediction unit 35 will be further described below.

In addition, a display unit 34 and the input unit 33 are connected to the controller 3. The controller 3 displays various pieces of information on the display unit 34. The operator of the heat treatment apparatus 1 can input various commands and parameters from the input unit 33 while checking the information displayed on the display unit 34. As the display unit 34 and the input unit 33, for example, a liquid crystal touch panel provided on the outer wall of the heat treatment apparatus 1 may be adopted. Furthermore, the IGBT 96 is connected to the controller 3, and the IGBT 96 is turned on and off by applying a pulse signal from the controller 3 to the gate of the IGBT 96. It should be noted that the storage unit 36 shown in FIG. 9 is a storage medium such as a magnetic disk or a memory of the controller 3.

The heat treatment apparatus 1 further includes, in addition to the aforementioned components, various cooling structures to prevent an excessive temperature rise in the halogen heating part 4, the flash heating part 5, and the chamber 6 because of the heat energy generated from the halogen lamps HL and the flash lamps FL during the heat treatment of a semiconductor wafer W. As an example, a water cooling tube (not shown) is provided in the walls of the chamber 6. Also, the halogen heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

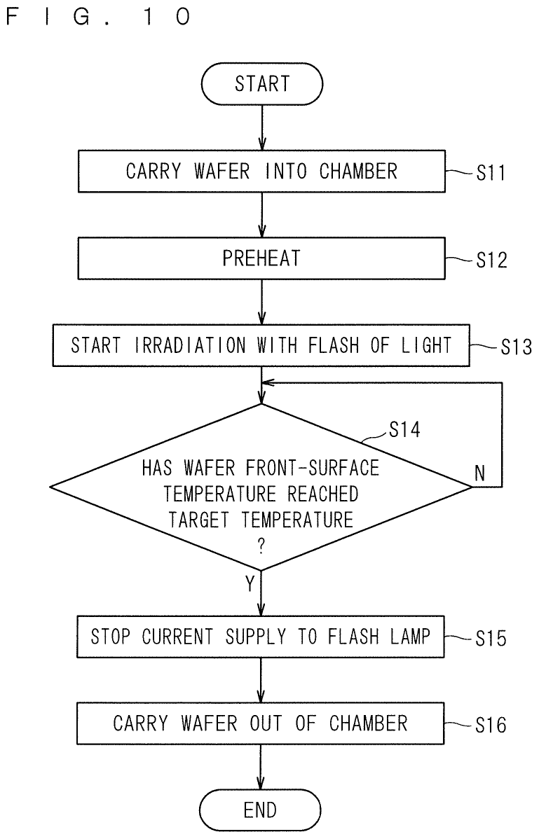

Next, the processing operation in the heat treatment apparatus 1 will be described. FIG. 10 is a flowchart showing a processing procedure of the heat treatment apparatus 1 according to the first embodiment. The semiconductor wafer W to be treated is a semiconductor substrate to which impurities (ions) have been added by the ion implantation method. Activation of the impurities is performed by a flash of light irradiation heating treatment (annealing) by the heat treatment apparatus 1. The treatment procedure of the heat treatment apparatus 1 described below proceeds by controlling each operating mechanism of the heat treatment apparatus 1 by the controller 3.

First, the valve 84 for air supply is opened, and the valves 89 and 192 for exhaust are opened to start air supply to and exhaust from the inside of the chamber 6. When the valve 84 is opened, nitrogen gas is supplied to the heat treatment space 65 from the gas supply opening 81. In addition, when the valve 89 is opened, the gas in the chamber 6 is exhausted from the gas exhaust opening 86. Thus, the nitrogen gas supplied from the upper portion of the heat treatment space 65 in the chamber 6 flows downward and is exhausted from the lower portion of the heat treatment space 65.

The gas within the chamber 6 is exhausted also through the transport opening 66 by opening the valve 192. Further, the exhaust mechanism not shown exhausts an atmosphere near the drivers of the transfer mechanism 10. It should be noted that during the heat treatment of the semiconductor wafer W in the heat treatment apparatus 1, nitrogen gas is continuously supplied to the heat treatment space 65, and the supply amount is appropriately changed according to the treatment step.

Subsequently, the gate valve 185 is opened and the transfer opening 66 is opened, and the transfer robot outside the apparatus carries the semiconductor wafer W to be treated into the heat treatment space 65 in the chamber 6 through the transfer opening 66 (step S11). At this time, the atmosphere outside the apparatus may be sucked as the semiconductor wafer W is carried in, but since nitrogen gas continues to be supplied to the chamber 6, nitrogen gas flows out from the transport opening 66, and suction of such an external atmosphere can be minimized.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. In addition, the semiconductor wafer W is held by the holder 7 with the front-surface on which the pattern is formed and impurities are implanted as the upper surface. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held from below in a horizontal attitude by the susceptor 74 of the holder 7 made of quartz, the forty halogen lamps HL of the halogen heating part 4 are turned on all at once to start preheating (assist heating) (step S12). The halogen light emitted from the halogen lamps HL passes through the lower chamber window 64 and the susceptor 74 made of quartz and is applied to the lower surface of the semiconductor wafer W. By receiving light irradiation from the halogen lamps HL, the semiconductor wafer W is preheated, so that the temperature of the semiconductor wafer W increases. It should be noted that since the transfer arms 11 of the transfer mechanism 10 are retracted inside the recessed portion 62, the transfer arms 11 do not hinder heating by the halogen lamps HL.

When the halogen lamps HL perform preheating, the temperature of the semiconductor wafer W is measured by the lower radiation thermometer 20. That is, the lower radiation thermometer 20 receives infrared light radiated through the opening 78 from the lower surface of the semiconductor wafer W held by the susceptor 74 through the transparent window 21 and measures the wafer temperature during temperature rise. The measured temperature of the semiconductor wafer W is transmitted to the controller 3. The controller 3 controls the output of the halogen lamps HL while monitoring whether or not the temperature of the semiconductor wafer W to be raised by light irradiation from the halogen lamps HL has reached a predetermined preheating temperature T1. That is, the controller 3 feedback-controls the output of the halogen lamps HL so that the temperature of the semiconductor wafer W reaches the preheating temperature T1 based on the measured value by the lower radiation thermometer 20. Thus, the lower radiation thermometer 20 is a radiation thermometer for controlling the temperature of the semiconductor wafer W during preheating. The preheating temperature T1 is in the range, in which there is no risk that impurities added to the semiconductor wafer W diffuse due to heat, of about 200° C. to 800° C., preferably about 350° C. to 600° C. (600° C. in the present embodiment).

After the temperature of the semiconductor wafer W reaches the preheating temperature T1, the controller 3 maintains the semiconductor wafer W at the preheating temperature T1 for a while. Specifically, when the temperature of the semiconductor wafer W measured by the lower radiation thermometer 20 reaches the preheating temperature T1, the controller 3 adjusts the output of the halogen lamps HL and maintains the temperature of the semiconductor wafer W at almost the preheating temperature T1.

Performing preheating with these halogen lamps HL uniformly raises temperature of the entire semiconductor wafer W to the preheating temperature T1. In the stage of preheating using the halogen lamps HL, the semiconductor wafer W shows a tendency to be lower in temperature in a peripheral portion thereof where heat dissipation is liable to occur than in a central portion thereof. However, the halogen lamps HL in the halogen heating part 4 are disposed at a higher density in the region opposed to the peripheral portion of the semiconductor wafer W than in the region opposed to the central portion thereof. This causes a greater amount of light to impinge upon the peripheral portion of the semiconductor wafer W where heat dissipation is liable to occur, thereby providing a uniform in-plane temperature distribution of the semiconductor wafer W in the stage of preheating.

In addition, from the time when the semiconductor wafer W is preheated, the front-surface temperature of the semiconductor wafer W is measured by the upper radiation thermometer 25. From the front-surface of the semiconductor wafer W to be heated, infrared light with an intensity corresponding to its temperature is radiated. The infrared light radiated from the front-surface of the semiconductor wafer W passes through the transparent window 26 and is received by the infrared sensor 29 of the upper radiation thermometer 25.

In the InSb optical element of the infrared sensor 29, a resistance change corresponding to the intensity of the received infrared light occurs. The resistance change occurring in the InSb optical element of the infrared sensor 29 is converted into a voltage signal by the signal conversion circuit 102. The voltage signal output from the signal conversion circuit 102 is amplified by the amplifier circuit 103 and then converted by the A/D converter 104 into a digital signal suitable for a computer to handle. Then, the temperature conversion unit 105 performs predetermined arithmetic processing on the signal output from the A/D converter 104 to convert the result into temperature data. That is, the upper radiation thermometer 25 receives infrared light radiated from the front-surface of the semiconductor wafer W to be heated, and measures the front-surface temperature of the semiconductor wafer W from the intensity of the infrared light. The front-surface temperature of the semiconductor wafer W measured by the upper radiation thermometer 25 is transmitted to the controller 3.

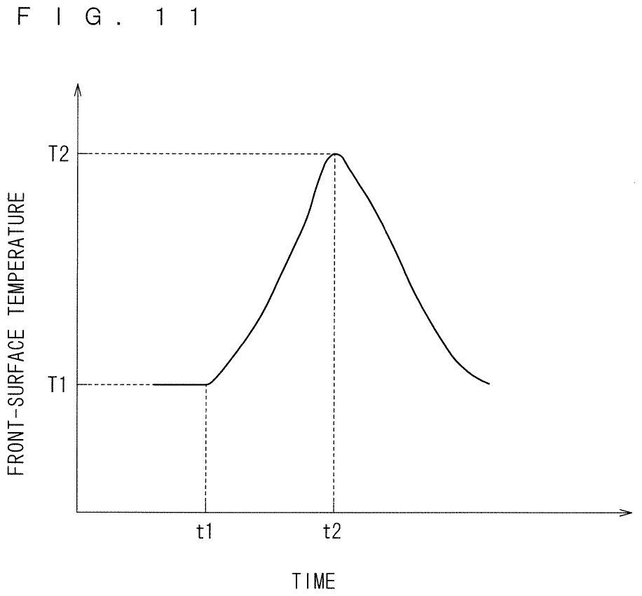

FIG. 11 is a diagram showing changes in the front-surface temperature of the semiconductor wafer W measured by the upper radiation thermometer 25. At time t1 when the temperature of the semiconductor wafer W reaches the preheating temperature T1 and a predetermined time elapses, the flash lamps FL of the flash heating part 5 starts irradiating the front-surface of the semiconductor wafer W held by the susceptor 74 with a flash of light (step S13). At this time, part of the flash of light emitted from the flash lamps FL travels directly toward the interior of the chamber 6. The remainder of the flash of light is reflected once from the reflector 52, and then travels toward the interior of the chamber 6. The irradiation of the semiconductor wafer W with such flashes of light achieves the flash heating of the semiconductor wafer W.

When the flash lamp FL performs irradiation with a flash of light, the power supply unit 95 stores electric charge in the capacitor 93 in advance. Then, in a state of the electric charge being stored in the capacitor 93, a pulse signal is output from the pulse generator 31 of the controller 3 to the IGBT 96 to on-off drive the IGBT 96.

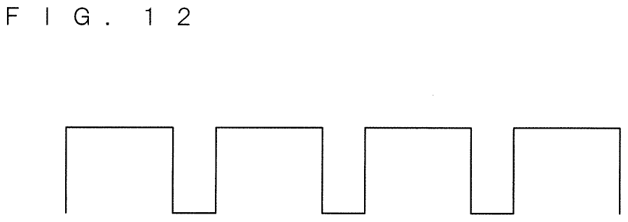

The waveform of the pulse signal can be defined by inputting a recipe in which the pulse width time (on time) and the pulse interval time (off time) are sequentially set as parameters from the input unit 33. When the operator inputs this recipe from the input unit 33 to the controller 3, the waveform setting unit 32 of the controller 3 accordingly sets a pulse waveform that repeats on and off. Then, the pulse generator 31 outputs a pulse signal according to the pulse waveform set by the waveform setting unit 32. FIG. 12 is a diagram showing an example of a waveform of a pulse signal. In the example shown in FIG. 12, a plurality of pulses are repeatedly set, and the time of the pulse width (ON time) is longer than the time of the pulse interval (OFF time). A pulse signal having a waveform as shown in FIG. 12 is applied to the gate of the IGBT 96, and on-off driving of the IGBT 96 is controlled. Specifically, when the pulse signal input to the gate of the IGBT 96 is on, the IGBT 96 is turned into an ON state, and when the pulse signal is off, the IGBT 96 is turned into an OFF state.

In addition, in synchronization with the timing at which the pulse signal output from the pulse generator 31 is turned on, the controller 3 controls the trigger circuit 97 to apply a high voltage (trigger voltage) to the trigger electrode 91. Inputting a pulse signal to the gate of the IGBT 96 with electric charge being stored in the capacitor 93 and applying a high voltage to the trigger electrode 91 in synchronization with the timing at which the pulse signal is turned on causes a current to flow between the electrodes at both ends in the glass tube 92 when the pulse signal is on, and light is emitted by the excitation of xenon atoms or molecules at that time.

In this way, the thirty flash lamps FL of the flash heating part 5 emit light, and the front-surface of the semiconductor wafer W held by the holder 7 is irradiated with a flash of light. In this case, when the flash lamps FL are made to emit light without using the IGBT 96, the electric charge stored in the capacitor 93 is consumed in one light emission, and the output waveform from the flash lamps FL has a simple single pulse of about 0.1 ms to 10 ms in width. On the other hand, in the present embodiment, connecting the IGBT 96 being a switching element in the circuit and outputting a pulse signal to the gate of the IGBT 96 intermittently supplies the electric charge from the capacitor 93 to the flash lamp FL with the IGBT 96 and on-off controls the current flowing through the flash lamp FL. As a result, the light emission of the flash lamp FL is, so to speak, chopper-controlled, the electric charge stored in the capacitor 93 is dividedly consumed, and the flash lamp FL repeats blinking in an extremely short time. It should be noted that before the current value flowing through the circuit becomes completely “0”, the next pulse is applied to the gate of the IGBT 96 and the current value increases again, so that the emission output is not completely “0” even while the flash lamp FL repeats blinking.

On-off controlling the current flowing through the flash lamp FL with the IGBT 96 allows the light emission pattern (time waveform of the light emission output) of the flash lamp FL to be flexibly defined, and the light emission time and the light emission intensity to be freely adjusted. The on-off drive pattern of the IGBT 96 is defined by the pulse width time and the pulse interval time input from the input unit 33. That is, incorporating the IGBT 96 in the drive circuit of the flash lamp FL allows the light emission pattern of the flash lamp FL to be flexibly defined simply by appropriately setting the pulse width time and the pulse interval time input from the input unit 33.

Specifically, for example, when the ratio of the pulse width time to the pulse interval time input from the input unit 33 is increased, the current flowing through the flash lamp FL increases and the light emission intensity increases. Conversely, when the ratio of the pulse width time to the pulse interval time input from the input unit 33 is reduced, the current flowing through the flash lamp FL is reduced and the light emission intensity decreases. In addition, if the ratio between the pulse interval time and the pulse width time input from the input unit 33 is appropriately adjusted, the light emission intensity of the flash lamp FL is maintained constant. Furthermore, increasing the total time of the combination of the pulse width time and the pulse interval time input from the input unit 33 causes the current to continue flowing through the flash lamp FL for a relatively long time, and the light emission time of the flash lamp FL to increase. The light emission time of the flash lamp FL is appropriately set between 0.1 ms and 100 ms.

In this way, the front-surface of the semiconductor wafer W is irradiated with a flash of light from the flash lamps FL, and the temperature of the front-surface rises. The upper radiation thermometer 25 also measures the front-surface temperature of the semiconductor wafer W during the temperature rise caused by the irradiation with a flash of light. Although the light emission time of the flash lamp FL is a short time of 0.1 milliseconds to 100 milliseconds, the sampling interval of the upper radiation thermometer 25 including the InSb optical element is an extremely short time of about 20 microseconds (that is, 50 points can be measured in 1 millisecond). Therefore, the upper radiation thermometer 25 can measure a change in the front-surface temperature of the semiconductor wafer W rapidly raised by irradiation with a flash of light (FIG. 11).

In the first embodiment, the controller 3 monitors whether the front-surface temperature of the semiconductor wafer W measured by the upper radiation thermometer 25 has reached the target temperature T2 (step S14). The target temperature T2 is a temperature required to achieve the purpose of the heating treatment of the semiconductor wafer W, and is 1000° C. or higher at which impurities implanted into the semiconductor wafer W can be activated in the present embodiment. The target temperature T2 is preset and stored in the storage unit 36.

When the front-surface temperature of the semiconductor wafer W measured by the upper radiation thermometer 25 reaches the target temperature T2 at time t2, the process proceeds from step S14 to step S15, and the current supply to the flash lamps FL is stopped under the control of the controller 3. Specifically, at time t2 when the front-surface temperature of the semiconductor wafer W reaches the target temperature T2, the controller 3 turns off the pulse signal applied to the gate of the IGBT 96.

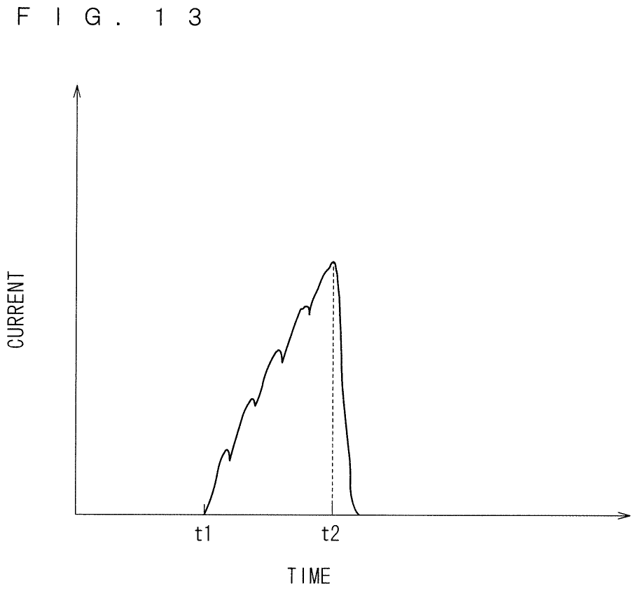

FIG. 13 is a diagram showing a change in current flowing through the flash lamps FL. At time t1, a pulse signal having a waveform as shown in FIG. 12 is applied to the gate of the IGBT 96, the current flowing through the flash lamp FL increases, and the flash lamp FL starts light emission. As shown in FIG. 12, since the pulse signal applied to the gate of the IGBT 96 repeats on and off, the current flowing through the flash lamp FL also repeats increase and decrease accordingly. That is, when the pulse signal applied to the gate of the IGBT 96 is on, the current flowing through the flash lamp FL increases, and when the pulse signal is off, the current flowing through the flash lamp FL decreases. In the example shown in FIG. 12, since the time during which the pulse signal is turned on is longer than the time during which the pulse signal is turned off, as shown in FIG. 13, the current flowing through the flash lamp FL increases as a whole while repeating increase and decrease. As the current flowing through the flash lamp FL increases, the light emission output of the flash lamp FL also increases.

Next, at time t2 when the front-surface temperature of the semiconductor wafer W reaches the target temperature T2, the controller 3 turns off the pulse signal applied to the gate of the IGBT 96. At this time, regardless of the waveform of the pulse signal set by the waveform setting unit 32, the controller 3 turns off the pulse signal applied to the gate of the IGBT 96. That is, even if the pulse signal set by the waveform setting unit 32 is on at time t2, the controller 3 forcibly turns off the pulse signal at time t2. Thus, the IGBT 96 is turned off at and after time t2, and the supply of the current to the flash lamp FL is stopped.

When the current supply to the flash lamps FL is stopped at time t2, the light emission of the flash lamps FL is also stopped, and the front-surface temperature of the semiconductor wafer W rapidly drops from the target temperature T2. Raising the front-surface temperature of the semiconductor wafer W to the target temperature T2 in an extremely short time and then lowering the temperature makes it possible to activate the impurities implanted into the semiconductor wafer W while suppressing the diffusion of the impurities due to heat.

The halogen lamps HL are turned off after a predetermined time has elapsed since the current supply to the flash lamps FL is stopped. Thus, the semiconductor wafer W rapidly drops in temperature from the preheating temperature T1. The temperature of the semiconductor wafer W during drop in temperature is measured by the lower radiation thermometer 20, and the measurement result is transmitted to the controller 3. The controller 3 monitors whether the temperature of the semiconductor wafer W has dropped to a predetermined temperature based on the measurement result of the lower radiation thermometer 20. Then, after the temperature of the semiconductor wafer W drops to a predetermined temperature or less, the pair of transfer arms 11 of the transfer mechanism 10 horizontally move from the retracted position to the transfer operation position again and rise, whereby the lift pins 12 protrude from the upper surface of the susceptor 74 and receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 to the outside (step S16). Thus, the heat treatment apparatus 1 completes the heating treatment of the semiconductor wafer W.

In the first embodiment, the upper radiation thermometer 25 measures the front-surface temperature of the semiconductor wafer W to be increased in temperature by irradiation with a flash of light from the flash lamps FL. Then, when the front-surface temperature of the semiconductor wafer W to be measured by the upper radiation thermometer 25 reaches the target temperature T2, the supply of current to the flash lamps FL is stopped to lower the front-surface temperature of the semiconductor wafer W. Since the supply of the current to the flash lamps FL is stopped when the actual measurement temperature of the front-surface of the semiconductor wafer W reaches the target temperature T2, the front-surface temperature of the semiconductor wafer W can be accurately raised to the target temperature T2 regardless of the front-surface state and reflectance of the semiconductor wafer W. As a result, even when a plurality of semiconductor wafers W are treated, the peak temperature becomes constant, and variations in device performance can be suppressed.

### Second Embodiment

Next, a second embodiment of the present invention will be described. The configuration of the heat treatment apparatus of the second embodiment is exactly the same as that of the first embodiment. In addition, the treatment procedure of the semiconductor wafer W in the second embodiment is also substantially the same as that in the first embodiment. In the first embodiment, the current supply to the flash lamps FL is stopped when the measured value of the front-surface temperature of the semiconductor wafer W reaches the target temperature T2. In the second embodiment, however, a scheduled arrival time at which the front-surface temperature of the semiconductor wafer W reaches the target temperature T2 is predicted, and the current supply to the flash lamps FL is stopped at the scheduled arrival time.

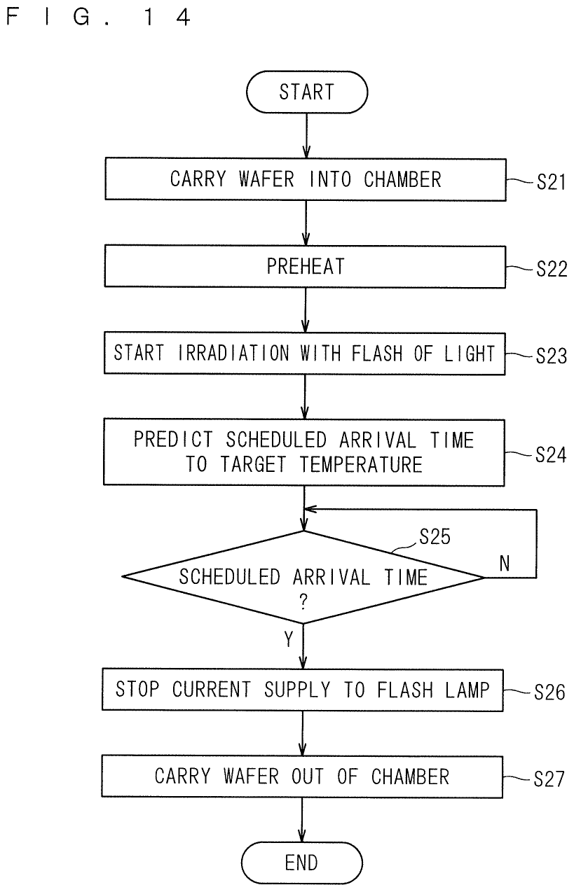

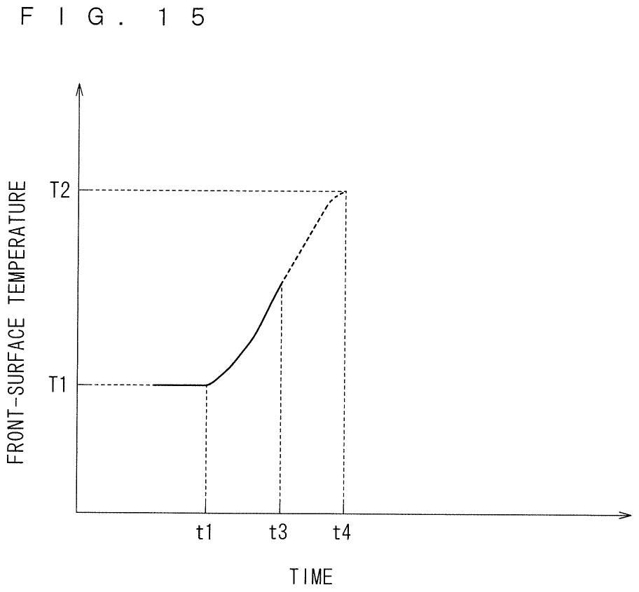

FIG. 14 is a flowchart showing a treatment procedure of the heat treatment apparatus 1 according to the second embodiment. Steps S21 to S23 in FIG. 14 are the same as steps S11 to S13 in FIG. 10. That is, the semiconductor wafer W to be treated is transported into the chamber 6 and held by the susceptor 74 (step S21). Subsequently, the halogen lamps HL are turned on to preheat the semiconductor wafer W (step S22). In addition, after the preheating is started, the upper radiation thermometer 25 measures the front-surface temperature of the semiconductor wafer W. FIG. 15 is a diagram showing changes in the front-surface temperature of a semiconductor wafer W according to the second embodiment. As in the first embodiment, at time t1 when a predetermined time has elapsed since the temperature of the semiconductor wafer W reached the preheating temperature T1 by preheating, the flash lamps FL start to irradiate the front-surface of the semiconductor wafer W with a flash of light (step S23). Also in the second embodiment, a pulse signal having a waveform as shown in FIG. 12 is applied to the gate of the IGBT 96 to cause the flash lamps FL to emit light, and the front-surface of the semiconductor wafer W is irradiated with a flash of light to raise the temperature of the front-surface.

In the second embodiment, at time t3 after the start of the irradiation with a flash of light and before the front-surface temperature of the semiconductor wafer W reaches the target temperature T2, the prediction unit 35 (FIG. 9) of the controller 3 predicts the change in the front-surface temperature of the semiconductor wafer W. More specifically, the prediction unit 35 predicts the scheduled arrival time t4 at which the front-surface temperature of the semiconductor wafer W reaches the target temperature T2 from the temperature measurement result obtained by the upper radiation thermometer 25 from time t1 to time t3 (step S24).

As shown in FIG. 9, the storage unit 36 of the controller 3 stores a plurality of temperature rise patterns PT (for example, temperature rise patterns for 1000 semiconductor wafers W) acquired by measuring the front-surface temperature of the semiconductor wafer W when irradiation with a flash of light has been performed in the past. That is, the storage unit 36 acquires temperature profiles indicating changes in front-surface temperature of a plurality of semiconductor wafers W during irradiation with a flash of light, and stores the temperature profiles as the temperature rise patterns PT. The prediction unit 35 compares the temperature measurement result by the upper radiation thermometer 25 from time t1 to time t3 with a plurality of temperature rise patterns PT being past results to predict the scheduled arrival time t4 at which the front-surface temperature of the semiconductor wafer W reaches the target temperature T2. The prediction unit 35 extracts a temperature rise pattern PT approximate to the temperature measurement result by the upper radiation thermometer 25 from time t1 to time t3 from the plurality of temperature rise patterns PT by, for example, a pattern matching method, and predicts the scheduled arrival time t4 at which the front-surface temperature of the semiconductor wafer W reaches the target temperature T2 from the extracted temperature rise pattern PT.

The controller 3 monitors whether or not the time reaches the scheduled arrival time t4 by a timer (not shown) (step S25). Then, when the time reaches the scheduled arrival time t4, the process proceeds from step S25 to step S26, and the current supply to the flash lamps FL is stopped under the control of the controller 3. Specifically, as in the first embodiment, the controller 3 turns off the pulse signal applied to the gate of the IGBT 96 at the scheduled arrival time t4. At this time, regardless of the waveform of the pulse signal set by the waveform setting unit 32, the controller 3 turns off the pulse signal applied to the gate of the IGBT 96. Thus, the IGBT 96 is turned off at and after the scheduled arrival time t4, and the supply of the current to the flash lamps FL is stopped.

When the current supply to the flash lamps FL is stopped at the scheduled arrival time t4, the light emission of the flash lamps FL is also stopped, and the front-surface temperature of the semiconductor wafer W rapidly drops from the target temperature T2. Raising the front-surface temperature of the semiconductor wafer W to the target temperature T2 in an extremely short time and then lowering the temperature makes it possible to activate the impurities implanted into the semiconductor wafer W while suppressing the diffusion of the impurities due to heat.

The halogen lamps HL are turned off after a predetermined time has elapsed since the current supply to the flash lamps FL is stopped. Thus, the semiconductor wafer W rapidly drops in temperature from the preheating temperature T1. Then, as in the first embodiment, after the temperature of the semiconductor wafer W drops to a predetermined temperature or less, the semiconductor wafer W is transported out of the chamber 6, and the heating treatment of the semiconductor wafer W in the heat treatment apparatus 1 is completed (step S27).

In the second embodiment, the upper radiation thermometer 25 measures the front-surface temperature of the semiconductor wafer W rising in temperature by irradiation with a flash of light from the flash lamps FL, and the scheduled arrival time t4 at which the front-surface temperature of the semiconductor wafer W reaches the target temperature T2 is predicted from the temperature measurement result. Then, at the scheduled arrival time t4, the supply of the current to the flash lamps FL is stopped to lower the front-surface temperature of the semiconductor wafer W. Since the supply of the current to the flash lamps FL is stopped at the scheduled arrival time t4 at which the front-surface temperature of the semiconductor wafer W is predicted to reach the target temperature T2, the front-surface temperature of the semiconductor wafer W can be accurately raised to the target temperature T2 regardless of the front-surface state and reflectance of the semiconductor wafer W. As a result, even when a plurality of semiconductor wafers W are treated, the peak temperature becomes constant, and variations in device performance can be suppressed.

<Modification>

While the preferred embodiment according to the present invention has been described hereinabove, various modifications of the present invention in addition to those described above may be made without departing from the scope and spirit of the invention. For example, in the second embodiment, the current supply to the flash lamps FL is stopped at the scheduled arrival time t4, but the present invention is not limited thereto, and the current supply to the flash lamps FL may be stopped before and after the scheduled arrival time t4 with a predetermined width. That is, the front-surface temperature of the semiconductor wafer W may be lowered by stopping current supply to the flash lamps FL within a predetermined period including the scheduled arrival time t4. The deviation width from the scheduled arrival time t4 of the time when the current supply is stopped has only to be set in advance and stored in the storage unit 36 or the like.

In addition, in the above embodiments, a pulse signal having a waveform in which a plurality of pulses are repeatedly set as shown in FIG. 12 is output. However, for example, a pulse signal having a waveform in which one long pulse is set may be input to the gate of the IGBT 96. Even in this case, when the measured front-surface temperature of the semiconductor wafer W reaches the target temperature T2, or at the scheduled arrival time t4, the controller 3 turns off the pulse signal applied to the gate of the IGBT 96, whereby the current supply to the flash lamps FL is stopped, and the same effect as in the above embodiments can be obtained.

In addition, in the above embodiments, the current supply to the flash lamps FL is stopped by turning off the IGBT 96, but the present invention is not limited thereto, and the current supply may be stopped by cutting off the charge supply from the capacitor 93 to the flash lamps FL using a switching element different from the IGBT 96. Alternatively, a mechanical shutter may be provided in the flash heating part 5, and the mechanical shutter may be closed at a predetermined timing to shield a flash of light emitted from the flash lamp FL.

Although the 30 flash lamps FL are provided in the flash heating part 5 according to the aforementioned preferred embodiment, the present invention is not limited to this. Any number of flash lamps FL may be provided. The flash lamps FL are not limited to the xenon flash lamps, but may be krypton flash lamps. Also, the number of halogen lamps HL provided in the halogen heating part 4 is not limited to 40. Any number of halogen lamps HL may be provided.

In the aforementioned preferred embodiment, the filament-type halogen lamps HL are used as continuous lighting lamps that emit light continuously for not less than one second to preheat the semiconductor wafer W. The present invention, however, is not limited to this. In place of the halogen lamps HL, discharge type arc lamps (e.g., xenon arc lamps) may be used as the continuous lighting lamps to perform the preheating.

In addition, the substrate to be treated by the heat treatment apparatus 1 is not limited to the semiconductor wafer, and may be a glass substrate used for a flat panel display such as a liquid crystal display apparatus or a substrate for a solar cell. In addition, in the heat treatment apparatus 1, heat treatment of a high dielectric constant gate insulating film (High-k film), bonding of metal and silicon, or crystallization of polysilicon may be performed.

### EXPLANATION OF REFERENCE SIGNS

1: heat treatment apparatus
3: controller
4: halogen heating part
5: flash heating part
6: chamber
7: holder
10: transfer mechanism
20: lower radiation thermometer
25: upper radiation thermometer
29: infrared sensor
33: input unit
34: display unit
35: prediction unit
36: storage unit
63: upper chamber window
64: lower chamber window
65: heat treatment space
74: susceptor
96: IGBT
101: high-speed radiation thermometer unit
105: temperature conversion unit
FL: flash lamp
HL: halogen lamp
W: semiconductor wafer

1. A heat treatment method for heating a substrate by irradiating the substrate with a flash of light, the heat treatment method comprising:
an irradiation with a flash of light step of irradiating a front-surface of a substrate with a flash of light from a flash lamp to raise a temperature of the front-surface;
a temperature measurement step of measuring a temperature of said front-surface of said substrate to be raised in temperature by a radiation thermometer; and
a light emission stopping step of stopping supply of a current to said flash lamp to lower a temperature of said front-surface when a temperature of said front-surface to be measured by said radiation thermometer reaches a target temperature.

2. A heat treatment method for heating a substrate by irradiating the substrate with a flash of light, the heat treatment method comprising:
an irradiation with a flash of light step of irradiating a front-surface of a substrate with a flash of light from a flash lamp to raise a temperature of the front-surface;
a temperature measurement step of measuring a temperature of said front-surface of said substrate to be raised in temperature by a radiation thermometer;
a prediction step of predicting a scheduled arrival time at which a temperature of said front-surface reaches a target temperature from a temperature measurement result by said radiation thermometer; and
a light emission stopping step of stopping supply of a current to said flash lamp to lower a temperature of said front-surface within a predetermined period including said scheduled arrival time predicted in said prediction step.

3. The heat treatment method according to claim 2, wherein said light emission stopping step includes stopping supply of a current to said flash lamp at said scheduled arrival time.

4. The heat treatment method according to claim 2 or 3, wherein
said prediction step includes predicting said scheduled arrival time based on a plurality of temperature rise patterns acquired when irradiation with a flash of light is performed.

5. The heat treatment method according to claim 1, wherein said light emission stopping step includes turning off an IGBT connected to said flash lamp to stop supply of a current to said flash lamp.

6. A heat treatment apparatus configured to irradiate a substrate with a flash of light to heat the substrate, the heat treatment apparatus comprising:
a chamber configured to accommodate a substrate;
a flash lamp configured to irradiate a front-surface of said substrate accommodated in said chamber with a flash of light to raise a temperature of the front-surface;
a radiation thermometer configured to measure a temperature of said front-surface of said substrate to be raised in temperature; and
a switching unit configured to stop supply of a current to said flash lamp to lower a temperature of said front-surface when a temperature of said front-surface to be measured by said radiation thermometer reaches a target temperature.

7. A heat treatment apparatus configured to irradiate a substrate with a flash of light to heat the substrate, the heat treatment apparatus comprising:
a chamber configured to accommodate a substrate;
a flash lamp configured to irradiate a front-surface of said substrate accommodated in said chamber with a flash of light to raise a temperature of the front-surface;
a radiation thermometer configured to measure a temperature of said front-surface of said substrate to be raised in temperature;
a prediction unit configured to predict a scheduled arrival time at which a temperature of said front-surface reaches a target temperature from a temperature measurement result by said radiation thermometer; and
a switching unit configured to stop supply of a current to said flash lamp to lower a temperature of said front-surface within a predetermined period including said scheduled arrival time predicted by said prediction unit.

8. The heat treatment apparatus according to claim 7, wherein said switching unit stops supply of a current to said flash lamp at said scheduled arrival time.

9. The heat treatment apparatus according to claim 7, further comprising a storage unit configured to store a plurality of temperature rise patterns acquired when irradiation with a flash of light is performed,
wherein said prediction unit predicts said scheduled arrival time based on said plurality of temperature rise patterns.

10. The heat treatment apparatus according to claim 6, wherein said switching unit includes an IGBT connected to said flash lamp.
